(19) United States
(12) Patent Application Publication
(10) Pub. No.: US 2007/0086262 A1
(43) Pub. Date: Apr. 19, 2007

(54) INTEGRATED CIRCUIT CHIP WITH CONNECTIVITY PARTITIONING

(75) Inventors: Chetan Verma, Noida (IN); Rohit Gupta, New Delhi (IN); Piyush K. Mishra, Noida (IN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 11/550,081

(22) Filed: Oct. 17, 2006

(30) Foreign Application Priority Data
Oct. 17, 2005 (IN) 2772/DEL/2005

(51) Int. Cl. G11C 8/00

(52) U.S. Cl. 365/230.03

(57) ABSTRACT

A semiconductor integrated circuit (IC) chip includes at least one core logic module located in a central area of the chip and having a core input/output (I/O) and a plurality of I/O pads disposed on a periphery of the chip. Narrow logic blocks including buffers and delay elements separate the core logic module from the I/O pads. The core I/O is coupled to the I/O pads by way of the buffers and delay elements of the narrow logic blocks.

### BACKGROUND OF THE INVENTION

The present invention relates to the layout of an integrated circuit (IC) and, more particularly, to an IC and a method of laying out an IC that addresses signal degradation due to long wire lengths between I/O pads and core logic blocks.

Semiconductor integrated circuit (IC) devices typically include semiconductor transistors such as metal oxide semiconductor (MOS) and complementary metal oxide semiconductor (CMOS) pairs that are interconnected by conductive pathways or routes to form logic blocks. The logic blocks are then coupled to a plurality of I/O pads for connection with external devices. Designs of semiconductor IC devices are increasingly being scaled down so that more transistors fit onto smaller surface areas.

With the downsizing of IC designs, interconnect delay are becoming more pronounced, which causes signal degradation due to relative increases in route length. Traditionally switching time was roughly proportional to the capacitance of the transistor gates. However, with transistors becoming smaller and more transistors being placed on the chip, interconnect capacitance (i.e., the capacitance of the wires connecting different parts of the chip) is becoming a larger percentage of capacitance as signals have to travel across the chip leading to increased delay and lower performance. Signal degradation leads to large transition times when route length is not controlled.

With increasing intellectual property (IP) reuse such as third-party IP reuse, the number of “hard-IPs” (i.e., fixed or forced designs that cannot be modified) in a chip is increasing, which means longer interconnect route lengths when a signal needs to traverse the hard-IPs. The longer interconnect route lengths (i.e., signal paths) lead to increased delays, poor transition times, and signal integrity problems. Even with the best floor planning and routing, routing lengths are increasing. Such increased lengths were manageable in 0.18 um and even in 0.13 um, but as chip sizes decrease, such as to 90 nm and lower, such increased routing paths are increasing delay times and impacting signal transition times.

Referring now to FIG. 1, a schematic block diagram of a conventional semiconductor IC chip 100 having two core logic modules 102 and 104 and a plurality of I/O pads 106 is shown. The core logic modules 102 and 104 are connected the plurality of I/O pads 106 via wires 108. Many of the I/O pads 106 selectively connect to both of the core logic modules 102 and 104, so it is difficult to design the IC layout with minimized route lengths to each of the I/O pads 106. The routing lengths between the core logic modules 102 and 104 and the I/O pads 106 are therefore relatively large, which affects signal delays, signal transition times, and signal integrity.

It is desirable to provide I/O pads and core partitioning on a semiconductor IC. It also is desirable to overcome signal delays due to long route lengths in a manner that does not increase chip lay out time.

### BRIEF DESCRIPTION OF THE SEVERAL VIEWS OF THE DRAWINGS

The foregoing summary, as well as the following detailed description of a preferred embodiment of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a schematic block diagram of a conventional semiconductor integrated circuit (IC) chip having a plurality of I/O pads connected to core logic modules;

FIG. 2 is a schematic block diagram of a semiconductor integrated circuit (IC) chip in accordance with a preferred embodiment of the present invention having a plurality of I/O pads coupled to core logic modules by way of narrow logic blocks; and

FIG. 3 is an enlarged, detailed schematic block diagram of the narrow logic block of the semiconductor IC chip of FIG. 2.

### DETAILED DESCRIPTION OF THE INVENTION

Certain terminology is used in the following description for convenience only and is not limiting. The words “right”, “left”, “lower”, and “upper” designate directions in the drawing to which reference is made. The words “inwardly” and “outwardly” refer direction toward and away from, respectively, the geometric center of the object described and designated parts thereof. The terminology includes the words above specifically mentioned, derivatives thereof and words of similar import. Additionally, the word “a,” as used in the claims and in the corresponding portions of the specification, means “at least one.”

Briefly stated, the present invention comprises a semiconductor integrated circuit (IC) chip including at least one core logic module located in a central area of the chip and having a core input/output (I/O) and a plurality of I/O pads disposed on a periphery of the chip. A narrow logic block is located between the core logic module and the I/O pads. The core I/O is coupled to the I/O pads by way of the narrow logic block. The narrow logic block includes buffers, delay elements and combinatorial gates that allow interconnects from the core I/O to the I/O pads to overcome adverse affects of increased transition times and signal skew. The additional logic gates may be used to accommodate any last minute logic changes without affecting the rest of the chip layout.

The present invention also comprises a method of forming a semiconductor integrated circuit (IC) chip that includes providing an IC chip substrate having a main surface and a periphery and generating at least one core logic module having core inputs and outputs. The at least one core logic module is placed on the main surface of the IC chip substrate and a plurality of I/O pads are formed on the periphery of the substrate. A narrow logic block is formed on the substrate between the I/O pads and the core logic module. The core inputs and outputs are coupled to the I/O pads by way of the logic block.

In yet another aspect, the present invention is directed to a semiconductor IC chip including a first core logic module disposed in a central area of the chip and having a first core input and a first core output and a second core logic module also disposed in a central area of the chip and having a second core input and a second core output. A plurality of I/O pads is disposed on a periphery of the chip. A plurality of narrow logic blocks is located between the first and second core modules and the I/O pads. More particularly, there is at least one narrow logic block located along each side of the chip between the I/O pads and the first and second core logic modules. The first and second core inputs and outputs are connected to the I/O pads by way of the narrow logic blocks.

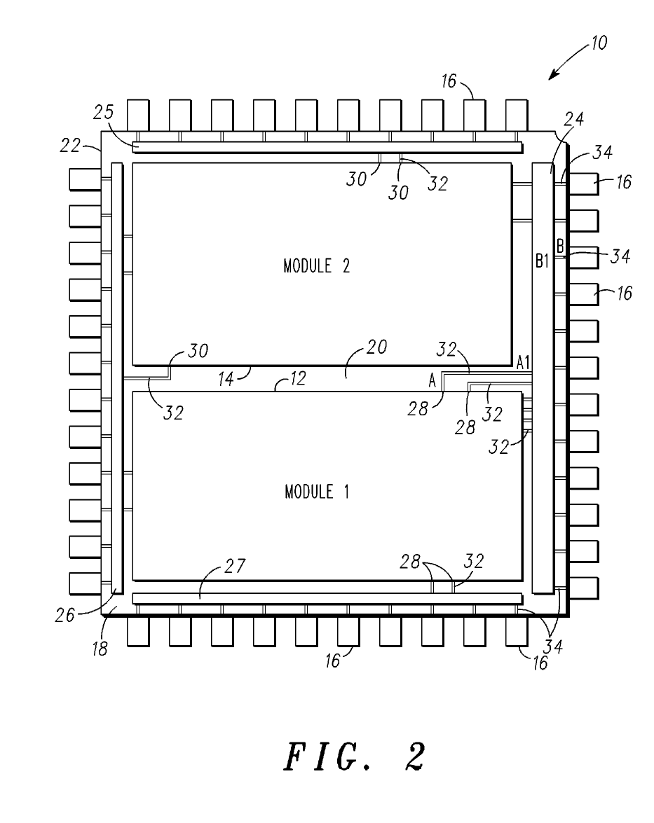

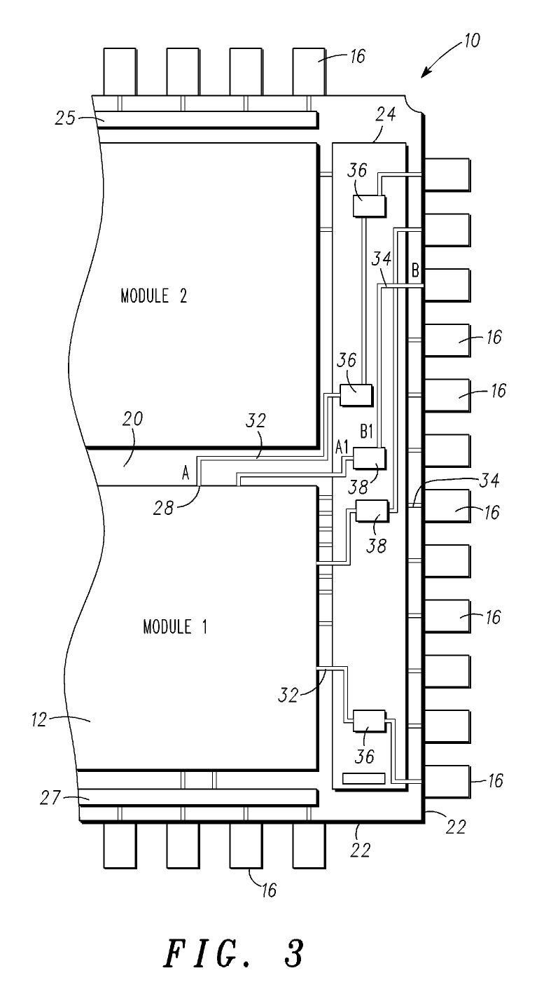

Referring to the drawings in detail, wherein like numerals reference indicate like elements throughout, there is shown in FIGS. 2-3 a semiconductor integrated circuit (IC) chip 10 in accordance with a first preferred embodiment of the present invention. The semiconductor IC chip 10 includes a first core logic module 12, a second core logic module 14, and a plurality of I/O pads 16. The first and second core logic modules 12 and 14 may comprise various hard-IPs, as are known to those of skill in the art, such as memories, arithmetic units, etc. The chip 10 may include one or more additional core logic modules (not shown) similar to the first and second core logic modules 12 and 14. The I/O pads 16 are of a type known to those of skill in the art and allow signals to be passed to and from the first and second core logic modules to circuits and devices outside of the chip 10.

The semiconductor IC chip 10 comprises a substrate 18 having a central area 20 in which the first and second core logic modules 12 and 14 are placed. The I/O pads 16 are located along the periphery of the chip 10, generally surrounding the substrate 20. As shown, the semiconductor IC chip 10 is rectangular or square, so the periphery comprises four sides or edges 22 and the I/O pads 16 are disposed along each of the four edges 22.

The chip 10 further includes a plurality of narrow logic blocks 24-27, which are located between the core logic modules 12, 14 and the I/O pads 16. The narrow logic blocks 24-27 are placed adjacent to the four edges 22 of the chip 10. Thus, a first narrow logic block 24 extends along the right edge, a second narrow logic block 25 extends along a top edge, a third narrow logic block 26 extends along a left edge, and a fourth narrow logic block 27 extends along a bottom edge of the chip 10. As the present invention is directed to partitioning the core logic modules 12 and 14 from the I/O pads 16, the narrow logic blocks 24-27 are core to I/O pads partitions.

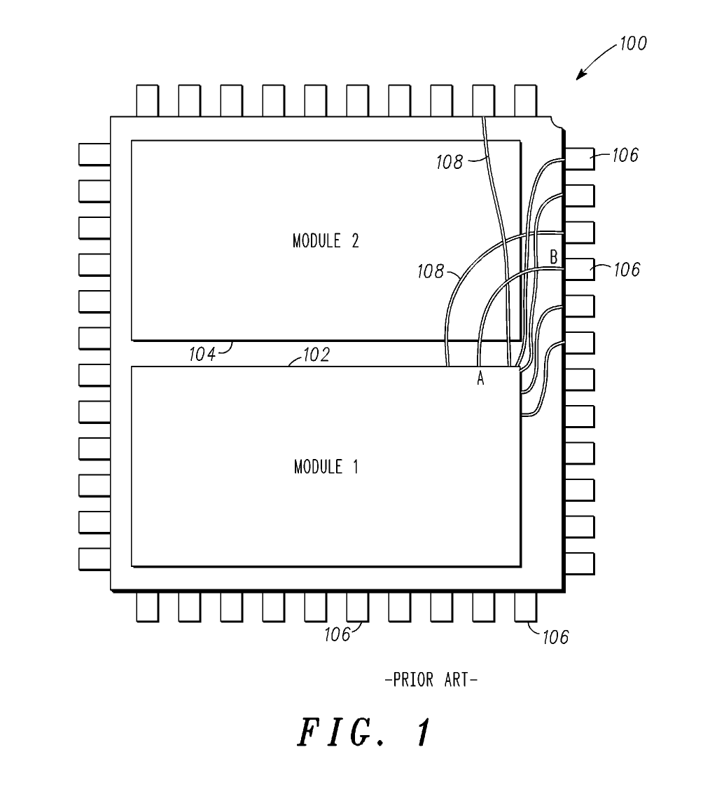

The first core logic module 12 includes a plurality of core input/outputs (I/O) 28 and the second core logic module 14 similarly includes a plurality of core I/O 30. The core I/O 28 and 30 may be configured as inputs or outputs or may selectively switch as inputs and outputs depending upon the application. The core I/O 28 and 30 may be located on all or a few of the sides of the first and second logic modules 12 and 14, respectively, as will be understood by those of skill in the art. As previously discussed, the I/O pads 16 are disposed on a periphery of the semiconductor IC chip 10. The narrow logic blocks 24-27 are located between and separate the first and second logic modules 12 and 14 from the I/O pads 16. A first plurality of wires or routes 32 connect the core I/O 28, 30 to the narrow logic blocks 24-27, and a second, separate plurality of routes 34 connect the narrow logic blocks 24-27 to the I/O pads 16. In the preferred embodiment of the invention, there are no direct connections from the core I/O 28, 30 to the I/O pads 16. Although it is contemplated that there are combinations of direct connections from the core I/O 28, 30 to the I/O pads 16 and indirect connections by way of the narrow logic blocks 24-37. As shown by contrasting the conventional chip 100 of FIG. 1 with the chip 10 of FIGS. 2-3, one conventional wire 108 from point A to B on FIG. 1, for example, is implemented in FIGS. 2-3 as two routes 32 and 34 with one of the narrow logic blocks 24-27 located therebetween. Thus, a similar connectivity path for A to B becomes a connectivity path from A to A1 and B1 to B via routes 32 and 34, respectively.

FIG. 3 is a detailed schematic diagram of one of the logic blocks 24. The other logic blocks 25-27 are similar to the logic block 24. The narrow logic block 24 includes at least one type of circuit element, namely, buffers 36, delay elements 38, or another type of combinatorial gate 40, but the narrow logic block 24 may include more than just one type of gate. That is, a narrow logic block 24-27 may include both buffers and delay elements. In the embodiment shown, a high-speed buffer 36 is used for long routing paths, which typically cause signal delays, and a delay element 38 is used to compensate for inter-signal skew. As will be understood by those of skill in the art, multiple buffers 36 or delay elements 38 sometimes are connected in series to provide for the desired buffering or delay. It also is possible that combinations of the buffers 36 and delay elements 38 can be connected in series. The logic blocks 24-27 may include other and/or additional circuit elements as well. The combinatorial logic gate 40 is used to accommodate last minute logic changes without affecting the entire chip layout.

The present invention also includes a method of forming a semiconductor IC chip 10. The method includes providing an IC chip substrate 18 having a central area 20 and edges 22 and placing at least one core logic module 12 having at least one core I/O 28 in the central area. Preferably, the core logic module 12 has a plurality of core I/O 28. The at least one core logic module 12 is surrounded by I/O pads 16, which are located along the periphery or edges 22 of the chip 10. A plurality of narrow logic blocks 24-27 are formed on the IC chip substrate 18 between the logic module 12 and the I/O pads 16. The core I/O 28 of the logic module 12 are connected to the I/O pads 16 by way of the narrow logic blocks 24-27.

By partitioning the core logic modules 12, 14 from the I/O pads 16, chip designs become more flexible because timing and delay violations caused by lengthy interconnects or routes 32 can be addressed in the logic blocks 24-27 without extensive and iterative re-routing of the routes 32. Partitioning the core logic 12, 14 from the I/O pads 16 and inserting the logic blocks 24-27 also provides more flexibility to designs because core logic development can occur in parallel to solving timing violations, which are resolved using the buffers and delays elements in the logic blocks 24-27. The logic blocks 24-27 are particularly useful in designs in nano-scale, i.e., 90 nanometers (nm) and less, where interconnect-delays are more pronounced than cell-delays. Signal integrity closure is more readily achieved inside the logic blocks 24-27 without impacting chip-level routing. Die size reduction can also be realized since the otherwise ‘loosely’ packed I/O-to-core region can be optimized with flexibility to iterate more without affecting the chip-level routing. The width of the logic blocks 24-27 is variable, and depends on the core to I/O pad connectivity. In one embodiment of the invention, for a CMOS90 chip having a size of 8300 microns×6300 microns, the narrow logic blocks have a width of between about 25 um to 45 um, and preferably about 35 um.

From the foregoing, it can be seen that the present invention is directed to a semiconductor IC chip having I/O pads and at least one core partition and a narrow logic block therebetween. The narrow logic block includes various logic circuits, such as high speed buffers, delay elements, and combinatorial gates. The high speed buffers allow signals that have poor signal transition times due to long wire lengths and the delay elements allow overcome inter-signal skew problems. Combinatorial gates allow for last minute logic changes. By using the narrow logic blocks, ad-hoc or piece meal fixing of signal delays and skew problems caused by long wire lengths is significantly reduced. The design team can work on other chip integration issues in parallel with the routing issues. Signal integrity issues are addressed within the narrow logic blocks so that chip level routing is not affected. Very late changes in pad ordering may be accommodated without affecting pin placement within the core logic modules. It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A semiconductor integrated circuit (IC) chip, comprising:
at least one core logic module having a core input/output (I/O) located in a central area of the chip;
a plurality of I/O pads disposed on a periphery of the chip; and
a narrow logic block coupled between the core I/O and at least one of the plurality of I/O pads.

2. The semiconductor IC chip according to claim 1, wherein the narrow logic block includes at least one of a plurality of buffers and a plurality of delay elements.

3. The semiconductor IC chip according to claim 1, wherein the narrow logic block includes a plurality of buffers and at least one of the core I/O is coupled to at least one of the I/O pads by way of at least one of the buffers.

4. The semiconductor IC chip according to claim 1, wherein the narrow logic block includes a plurality of delay elements and at least one of the core I/O is coupled to at least one of the I/O pads by way of at least one of the delay elements.

5. The semiconductor IC chip according to claim 1, wherein the narrow logic block includes a plurality of combinatorial logic gates and at least one of the core I/O is coupled to at least one of the I/O pads by way of at least one of the combinatorial logic gates.

6. The semiconductor IC chip according to claim 1, wherein the narrow logic block has a width of about 35 um.

7. A semiconductor integrated circuit (IC) chip, comprising:
a first core logic module disposed in a central area of the chip and having a plurality of first core inputs and first core outputs;
a second core logic module disposed in a central area of the chip and having a plurality of second core inputs and second core outputs;
a plurality of input/output (I/O) pads disposed around a periphery of the chip; and
a plurality of narrow logic blocks disposed between the first and second core logic modules and the plurality of I/O pads, wherein respective ones of the plurality of narrow logic blocks are located along respective sides of the chip such that the narrow logic blocks separate the first and second core logic modules from the I/O pads, and wherein selected ones of the first and second core inputs and outputs are coupled to selected ones of the I/O pads by way of respective ones of the plurality of narrow logic blocks.

8. The semiconductor IC chip according to claim 7, wherein the narrow logic blocks includes at least one of a plurality of buffers and a plurality of delay elements.

9. The semiconductor IC chip according to claim 8, wherein the selected ones of the first and second core inputs and the first and second core outputs are coupled to respective ones of the I/O pads by way of respective ones of the buffers and the delay elements.

10. The semiconductor IC chip according to claim 7, wherein the narrow logic blocks have a width of about 35 um.

11. A method of forming a semiconductor integrated circuit (IC) chip, comprising:
providing an IC chip substrate having a central area and a periphery;
generating at least one core logic module having core inputs and outputs;
placing the at least one core logic module in the central area of the IC chip substrate;
forming a plurality of input/output pads on the periphery of the IC chip substrate;
placing a narrow logic block on the IC chip substrate between the I/O pads and the core logic module; and
electrically coupling selected ones of the core inputs and outputs to selected ones of the I/O pads by way of the narrow logic block.

12. The method of forming a semiconductor IC chip of claim 11, wherein the narrow logic block includes at least one of a plurality of buffers and a plurality of delay elements.

13. The method of forming a semiconductor integrated circuit (IC) chip of claim 11, wherein the narrow logic block includes a plurality of buffers and the core inputs and outputs are electrically connected to respective ones of the I/O pads by way of respective ones of the plurality of buffers.

14. The method of forming a semiconductor integrated circuit (IC) chip of claim 11, wherein the narrow logic block includes a plurality of delay elements and the core inputs and outputs are electrically connected to respective ones of the I/O pads by way of respective ones of the plurality of delay elements.

15. The semiconductor IC chip according to claim 11, wherein the narrow logic block includes a plurality of combinatorial logic gates and at least one of the core inputs and outputs is coupled to at least one of the I/O pads by way of at least one of the combinatorial logic gates.

16. The method of forming a semiconductor IC chip of claim 11, wherein the narrow logic block has a width of about 35 um.
